(19) United States
(12) Patent Application Publication
(10) Pub. No.: US 2026/0247887 A1
(43) Pub. Date: Aug. 20, 2026

(54) ETCHING METHOD AND ETCHING APPARATUS

(71) Applicant: Tokyo Electron Limited, Tokyo (JP)

(72) Inventors: Keiji TANOUCHI, Nirasaki City (JP); Seungmin KIM, Hwaseong-si (KR); Yoshiaki OKAMOTO, Nirasaki City (JP); Shusuke OZAWA, Nirasaki City (JP); Sho NATABE, Nirasaki City (JP)

(21) Appl. No.: 19/642,761

(22) Filed: Apr. 9, 2026

Related U.S. Application Data
(63) Continuation of application No. PCT/JP2024/036181, filed on Oct. 9, 2024.

(30) Foreign Application Priority Data
Oct. 16, 2023 (JP) 2023-178404

(51) Int. Cl. H10P 50/28; H10P 72/00

(52) U.S. Cl. CPC H10P 50/283; H10P 72/0421

(57) ABSTRACT

An etching method of the present disclosure includes: a first gas supply process of supplying a fluorine-containing gas during a first period into a processing container which accommodates a substrate on which a silicon oxide film is formed; a second gas supply process of supplying a basic gas into the processing container during a second period including a common supply period overlapping the first period; and a first exhaust process of exhausting an interior of the processing container so that a pressure within the processing container during the common supply period becomes a first pressure greater than 50 Torr to perform etching of the silicon oxide film by the fluorine-containing gas and the basic gas.

### CROSS-REFERENCE TO RELATED APPLICATION

The application is a Bypass Continuation Application of PCT International Application No. PCT/JP2024/036181, filed on Oct. 9, 2024 and designating the United States, the international application being based upon and claiming the benefit of priority from Japanese Patent Application No. 2023-178404, filed on Oct. 16, 2023, the entire contents of which are incorporated herein by reference.

### TECHNICAL FIELD

The present disclosure relates to an etching method and an etching apparatus.

### BACKGROUND

In manufacturing a semiconductor device, there is a case in which a silicon oxide film formed on a surface of a semiconductor wafer (hereinafter, referred to as a “wafer”), which is a substrate, is etched. Patent Document 1 describes a technique in which HF gas and NH₃ gas are supplied to the silicon oxide film on the surface of the wafer to generate ammonium fluorosilicate (AFS), which is a reaction product, and then the wafer is heated to vaporize the AFS, thereby performing etching.

### PRIOR ART DOCUMENT

[Patent Document]
Patent Document 1: Japanese Patent Laid-Open Publication No. 2021-180281

### SUMMARY

An etching method of the present disclosure includes: a first gas supply process of supplying a fluorine-containing gas during a first period into a processing container which accommodates a substrate on which a silicon oxide film is formed; a second gas supply process of supplying a basic gas into the processing container during a second period including a common supply period overlapping the first period; and a first exhaust process of exhausting an interior of the processing container so that a pressure within the processing container during the common supply period becomes a first pressure greater than 50 Torr to perform etching of the silicon oxide film by the fluorine-containing gas and the basic gas.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional side view of an etching apparatus according to an embodiment of the present disclosure.

FIG. 2 is a view for explaining a processing operation in the etching apparatus.

FIG. 3 is a view for explaining a processing operation in the etching apparatus.

FIG. 4 is a view for explaining a processing operation in the etching apparatus.

FIG. 5 is a view for explaining a processing operation in the etching apparatus.

FIG. 6 is a view for explaining a processing operation in the etching apparatus.

FIG. 7 is a chart illustrating supply and stop of gases into a processing container and a change in pressure within the processing container.

FIG. 8 is a longitudinal cross-sectional side view of a wafer before and after etching.

FIG. 9 is a graph illustrating a result of an evaluation test.

FIG. 10 is a view for explaining a processing example in an evaluation test.

FIG. 11 is a view for explaining a processing example in the evaluation test.

FIG. 12 is a view for explaining a processing example in the evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

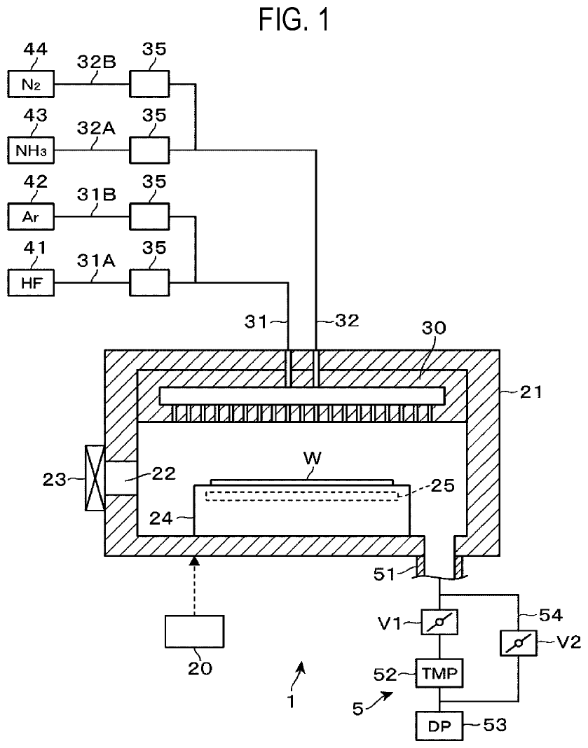

An embodiment of an etching method of the present disclosure will now be described. FIG. 1 is a longitudinal cross-sectional side view of an etching apparatus 1 for implementing the etching method. The etching apparatus 1 etches a film formed on a surface of a wafer W, which is a substrate, in a non-plasma environment under a vacuum atmosphere. Etching target films are a thermal oxide film 11 and a silicon oxide film 12. The thermal oxide film 11 is a silicon oxide film obtained by heating a silicon film to a temperature of 700 degrees C. or higher in an oxygen atmosphere or a water vapor atmosphere, which is a non-plasma environment.

The silicon oxide film 12 is another silicon oxide film of a type different from the thermal oxide film 11. Specifically, examples of the silicon oxide film 12 include a silicon oxide film formed by a chemical vapor deposition (CVD) or an atomic layer deposition (ALD), a silicon oxide film containing an added element such as a phosphorous silicate glass (PSG) film or a borosilicate glass (BSG) film, and a film obtained by oxidizing silicon in a plasma environment. A film formation by a CVD or an ALD includes both a film formation in a plasma environment and a film formation in a non-plasma environment. Further, the silicon oxide film formed by the CVD or the ALD includes a silicon oxide film formed by supplying tetra ethoxy silane (TEOS) gas as a film formation gas to the wafer W, and such a silicon oxide film may hereinafter be referred to as a TEOS film. In order to avoid confusion with the thermal oxide film 11, the silicon oxide film 12 may hereinafter be referred to as a non-thermal oxide film 12.

It is desired to increase an etching rate (an etching amount per unit time) of the thermal oxide film 11, and in some cases, it is required that the etching rate of the thermal oxide film 11 be higher than an etching rate of the non-thermal oxide film 12. The etching apparatus 1 is configured to meet the demand described above. In an etching process performed in the etching apparatus 1, hydrogen fluoride (HF) gas is used as a fluorine-containing gas, and ammonia (NH₃) gas is used as a basic gas. HF and NH₃ react with each other to generate (NH₄) F, which undergoes a decomposition reaction. As expressed by Equation 1 and Equation 2 below, two types of reactions can occur in the decomposition reaction described above. Thus, by the decomposition of NH₄F, HF and NH₃ are generated (that is, returning to a state prior to the generation of NH₄F), or HF₂ is generated. Regarding HF₂, it is known that an etchability for the thermal oxide film 11 is relatively high, whereas an etchability for the non-thermal oxide film 12 is relatively low.

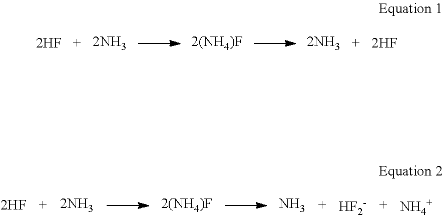

As shown in evaluation tests described later, it was confirmed that a generation of HF₂ is promoted under a relatively high pressure. Therefore, in supplying the HF gas and the NH₃ gas, which are etching gases, into a processing container 21 which accommodates the wafer W, a pressure in the processing container 21 is set to such a relatively high pressure, specifically, a pressure higher than 50 Torr (6,665 Pa). As described above, a relatively large amount of HF₂ is generated, so that the etching rate of the thermal oxide film 11 is increased.

Further, in the evaluation tests, it was confirmed that the etching rate of the thermal oxide film 11 is further increased by setting a start timing of supply of the HF gas and a start timing of supply of the NH₃ gas into the processing container 21 to be offset from each other or by supplying an inert gas into the processing container 21, which is in a relatively high pressure state, after the supply of the HF gas and the NH₃ gas is stopped. The etching apparatus 1 is also configured to perform such an operation control, and by performing such operation control, the etching rate of the thermal oxide film 11 is made higher than the etching rate of the non-thermal oxide film 12.

In addition, the etching apparatus 1 performs the etching at a relatively high pressure as described above, whereas after the etching, the etching apparatus 1 exhausts an interior of the processing container 21 at high speed so that the interior of the processing container 21 reaches a relatively low pressure. Thereby, the etching apparatus 1 is configured to quickly remove etching gases remaining in the processing container 21 or reaction products generated from the etching gases.

A configuration of the etching apparatus 1 will be described in more detail. As described above, the etching apparatus 1 includes the processing container 21. In the drawing, reference numeral 22 denotes a transfer port for the wafer W, which is opened in a side wall of the processing container 21 and is opened and closed by a gate valve 23. A stage 24 on which the wafer W is placed is provided in the processing container 21, and a lifting pin (not shown) is provided at the stage 24. An upper end of the lifting pin is protruded from and depressed into an upper surface of the stage 24. The wafer W is delivered between a substrate transfer mechanism (not shown) and the stage 24 via the lifting pin.

A temperature adjuster 25 is embedded in the stage 24 to heat the wafer W placed on the stage 24 to a set temperature of, for example, 100 degrees C. or higher. The temperature adjuster 25 may be configured, for example, as a part of a circulation path through which a temperature adjustment fluid flows, so that the fluid flows through the circulation path by a chiller, and a temperature of the wafer W may be adjusted by a heat exchange with the fluid. Alternatively, the temperature adjuster 25 may be configured by a heater that performs a resistance heating.

A gas shower head 30 is provided in an upper portion of the processing container 21 so as to face the stage 24. Downstream sides of gas supply paths 31 and 32 are connected to the gas shower head 30. An upstream side of the gas supply path 31 is branched to form gas supply paths 31A and 31B, and an upstream side of the gas supply path 32 is branched to form gas supply paths 32A and 32B. Upstream sides of the gas supply paths 31A, 31B, 32A, and 32B are respectively connected to gas supply sources 41, 42, 43, and 44 via respective flow rate adjusters 35. Each of the flow rate adjuster 35 includes a valve and a mass flow controller to perform supply and stop of gases supplied from the gas supply sources 41 to 44 to downstream sides and perform a flow rate adjustment of the gases.

HF gas, argon (Ar) gas, NH₃ gas, and nitrogen (N₂) gas are supplied from the gas supply sources 41, 42, 43, and 44 to the corresponding paths, respectively. The N₂ gas and the Ar gas are the inert gases described above. By the respective flow rate adjusters 35 as described above, it is possible to perform a switching of the gases supplied from the gas supply sources 41 to 44 into the processing container 21. The flow rate adjuster 35 in the gas supply path 31A and the gas supply source 41 supplying the HF gas corresponds to a first gas supply, and the flow rate adjuster 35 in the gas supply path 32A and the gas supply source 43 supplying the NH₃ gas corresponds to a second gas supply.

An upstream end of an exhaust path 51 is connected to a bottom portion of the processing container 21 and is opened into the processing container 21. In the exhaust path 51, a valve V1 and a turbo molecular pump 52, which is a second exhaust mechanism, are provided in this order toward a downstream side, and a downstream end of the exhaust path 51 is connected to a dry vacuum pump 53, which is a first exhaust mechanism. In addition, although the dry vacuum pump 53 is exemplified as the first exhaust mechanism, the first exhaust mechanism is not limited to the dry vacuum pump 53 and may be constituted by a rotary pump. Hereinafter, the turbo molecular pump 52 is referred to as TMP 52, and the dry vacuum pump 53 is referred to as DP 53.

In the exhaust path 51, which is a first exhaust path, an upstream end of an exhaust path 54, which is a second exhaust path, is connected to an upstream side of the valve V1, and a downstream end of the exhaust path 54 is connected to a downstream side of the TMP 52. In addition, a valve V2 is provided in the exhaust path 54. The valve V1, which is a first valve, and the valve V2, which is a second valve, are automatic pressure control (APC) valves, and a degree of opening of the valves V1 and V2 during a processing of the wafer W can be changed according to a control signal output from a controller 20 described later, so that a pressure within the processing container 21 is set to a preset value. The exhaust paths 51 and 54, the valves V1 and V2, the TMP 52, and the DP 53 are collectively referred to as an exhauster 5.

The TMP 52 is a main pump for use in exhausting the interior of the processing container 21 so that the interior of the processing container 21 reaches a relatively high degree of vacuum (that is, a relatively low pressure). Further, the DP 53 is an auxiliary pump that exhausts the interior of the processing container 21 up to a pressure at which the TMP 52 can operate when achieving such a high degree of vacuum and also exhausts a back pressure of the TMP 52 to the pressure at which the TMP 52 can operate. That is, in order to achieve a relatively high degree of vacuum within the processing container 21, both the TMP 52 and the DP 53, which are vacuum pumps, are used. On the other hand, when achieving a relatively low degree of vacuum (that is, a relatively high pressure) within the processing container 21, such as during a supply of etching gas, only the DP 53 among the TMP 52 and DP 53 is used.

As is well known, the TMP 52 is configured to discharge molecules, which have entered from an inlet port, toward an exhaust port by a rotating rotor blade, so that it is possible to exhaust at high-speed. However, when the pressure within the processing container 21 facing the inlet port is relatively high, there is a concern that the rotor blade may be damaged. On the other hand, as described above, during the supply of the etching gas, it is necessary to set the interior of the processing container 21 to a relatively low degree of vacuum in order to generate HF₂⁻, and after the supply of the etching gas is stopped, it is desirable to set the interior of the processing container 21 to a relatively high degree of vacuum in order to remove residues. Therefore, switching between the vacuum pumps to be used is performed to protect the TMP 52 by allowing the degree of vacuum within the processing container 21 to be switched.

An operation of the exhauster 5 will now be described in more detail. When increasing the degree of vacuum within the processing container 21 to a relatively high level, an operation (referred to as a “first operation”), in which the valve V1 is opened to adjust an opening degree of the valve V1, the valve V2 is closed, and the interior of the processing container 21 is exhausted by actions of the TMP 52 and the DP 53, is performed. Therefore, in the first operation, the interior of the processing container 21 is exhausted without passing through the exhaust path 54 and the valve V2. Further, when lowering the degree of vacuum within the processing container 21 to a relatively low level, an operation (referred to as a “second operation”), in which the valve V2 is opened to adjust the degree of opening of the valve V2, the valve V1 is closed, and the interior of the processing container 21 is exhausted by an action of only the DP 53 among the TMP 52 and the DP 53, is performed.

As described above, the etching apparatus 1 includes the controller 20, which is a computer, and the controller 20 includes a program, a memory, and a CPU. The program includes instructions (corresponding to individual steps) so that the processing of the wafer W and the transfer of the wafer W described above are performed. In addition, the program is stored in a non-transitory computer readable storage medium, for example, a compact disc, a hard disk, a magneto-optical disc, or a DVD, and is installed in the controller 20. The controller 20 outputs control signals to respective parts of the etching apparatus 1 according to the program to control an operation of each part. The operations controlled as described above include, for example, an adjustment of a temperature of the stage 24 (that is, the temperature of the wafer W), the operation of the exhauster 5, supply and stop of each gas from the gas supply sources 41 to 44 into the processing container 21 by the flow rate adjusters 35, the adjustment of flow rates and the like. The operation control of the exhauster 5 specifically includes an operation of the TMP 52 and the DP 53 and an adjustment of the degrees of opening of the valves V1 and V2 to adjust the pressure within the processing container 21.

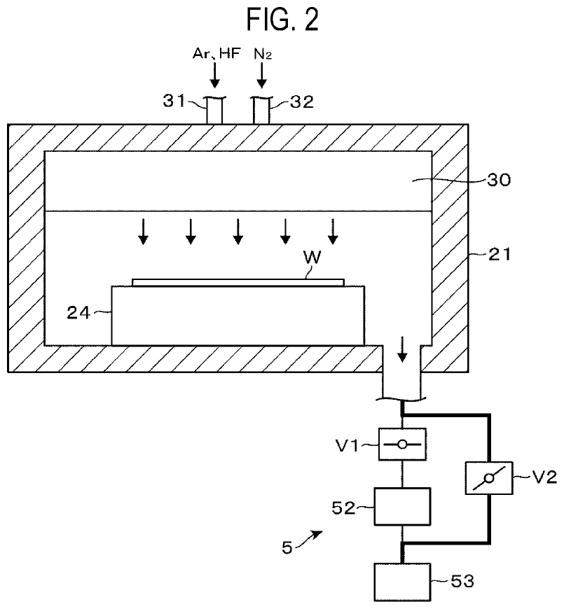

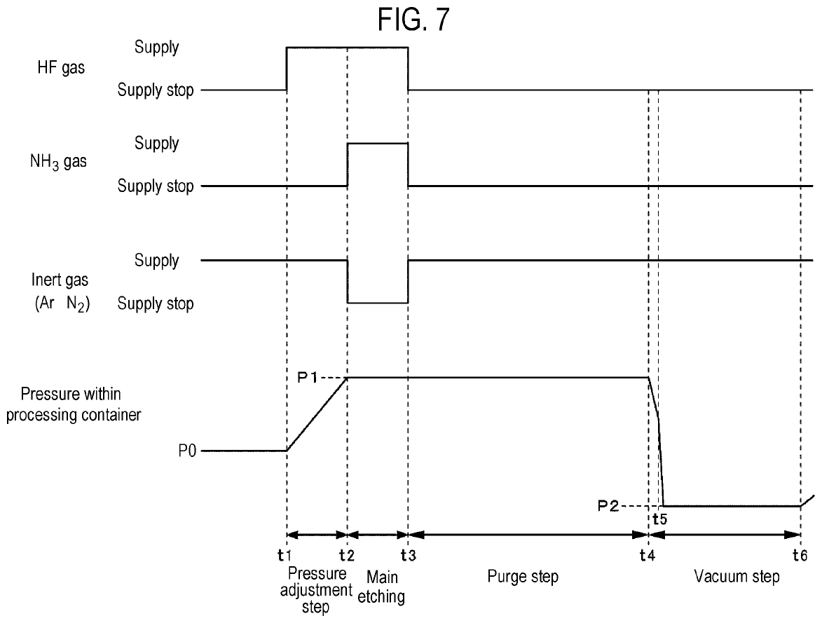

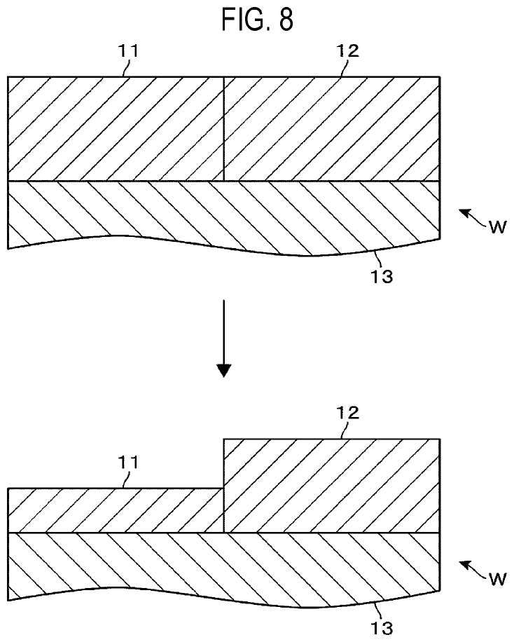

Subsequently, a processing operation in the etching apparatus 1 and a phenomenon considered to occur during the processing of the wafer W will be described with reference to explanatory views of FIGS. 2 to 6 schematically illustrating the etching apparatus 1, a time chart of FIG. 7, and a schematic longitudinal cross-sectional view of the wafer W of FIG. 8. In FIGS. 2 to 6, a flow path in which an exhaust flow is formed in the exhauster 5 is illustrated thicker than a flow path in which no exhaust flow is formed, and open and closed states of the valves V1 and V2 in the exhauster 5 are distinguished and illustrated according to angles of valve bodies. The time chart illustrates changes in the pressure within the processing container 21 and timings of the supply and stop of each gas into the processing container 21. The timings of the supply and stop of each gas may also be regarded as opening and closing timings of a valve constituting the flow rate adjusters 35.

First, the wafer W is loaded into the processing container 21 by the transfer mechanism (not shown). As shown at an upper part of FIG. 8, the thermal oxide film 11 and the non-thermal oxide film 12 are formed on an underlying film 13, and the thermal oxide film 11 and the non-thermal oxide film 12 form a surface of the wafer W. The wafer W is placed on the stage 24, the gate valve 23 of the processing container 21 is closed, and inert gases (Ar gas and N₂ gas) are respectively supplied from the gas supply paths 31 and 32 of a gas supply mechanism. The exhauster 5 is set to a state of the first operation which uses the TMP 52, and the pressure within the processing container 21 is set to a relatively low pressure P0, for example, 10 Torr (1,333 Pa).

Thereafter, since supply of the HF gas into the processing container 21 from the gas supply path 31 is started, both the HF gas and the Ar gas are supplied from the gas supply path 31, and a degree of opening of the valve V1 is changed so that the pressure within the processing container 21 starts to increase (time t1 in the chart). Subsequently, the valve V1 is closed, and the valve V2 is opened, so that the exhauster 5 is switched to a state of the second operation, and by adjusting a degree of opening of the valve V2, the pressure within the processing container 21 is further increased (FIG. 2). In parallel with the increase in pressure, the temperature of the wafer W reaches the above-described set temperature.

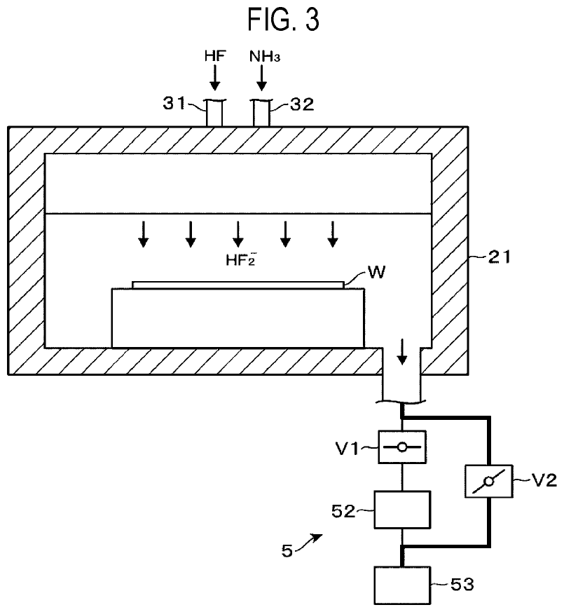

When the interior of the processing container 21 reaches a pressure P1, which is a first pressure higher than 50 Torr, for example, 90 Torr (1.2×10⁴ Pa) (time t2), the increase in pressure within the processing container 21 is stopped, and the pressure is maintained at P1. When the pressure is maintained as described, supply of the Ar gas and the N₂ gas from the gas supply paths 31 and 32 into the processing container 21 is respectively stopped and supply of the NH₃ gas from the gas supply path 32 into the processing container 21 is started (FIG. 3, time t2).

The etching gases (HF gas and NH₃ gas) supplied into the processing container 21 react with each other as shown in Equation 2 described above to generate HF₂⁻, and the HF₂ is supplied to the wafer W. By an action of the HF₂, the thermal oxide film 11 is etched to a relatively large extent, while etching of the non-thermal oxide film 12 is suppressed. Further, for example, flow rates of the HF gas and the NH₃ gas supplied to the processing container 21 are equal, and a partial pressure of each of the HF gas and the NH₃ gas within the processing container 21 is 90 Torr/2=45 Torr.

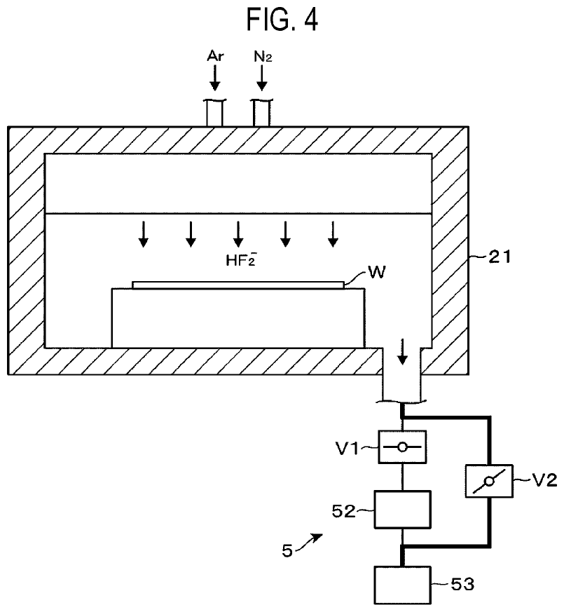

Thereafter, the supply of the HF gas and the NH₃ gas into the processing container 21 is stopped and the supply of the inert gases (Ar gas and N₂ gas) into the processing container 21 is resumed (FIG. 4, time t3). The pressure within the processing container 21 is maintained at the relatively high pressure P1. Therefore, since an exhaust within the processing container 21 is suppressed, a relatively large amount of the etching gases (HF gas and NH₃ gas) remains within the processing container 21. By supplying the inert gases, a flow of the HF gas and NH₃ gas within the processing container 21 is promoted and an agitation is achieved, so that a mixing and a reaction between the HF gas and NH₃ gas is promoted. Therefore, HF₂ is generated continuously. The inert gases cause the HF₂ to flow toward the wafer W, and thus etching of the thermal oxide film 11 further proceeds.

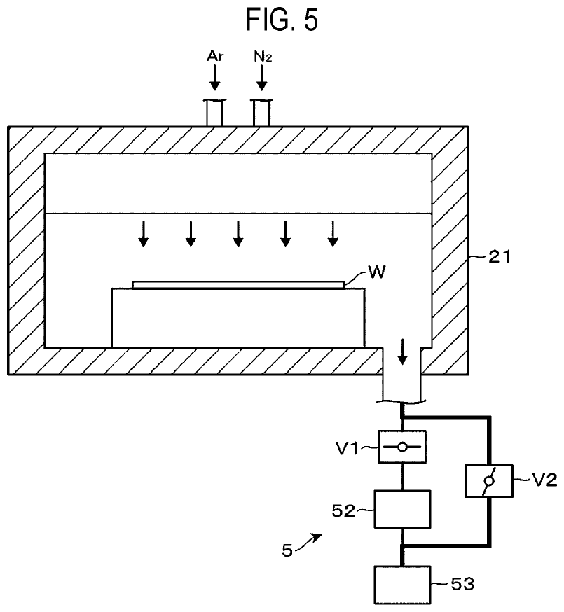

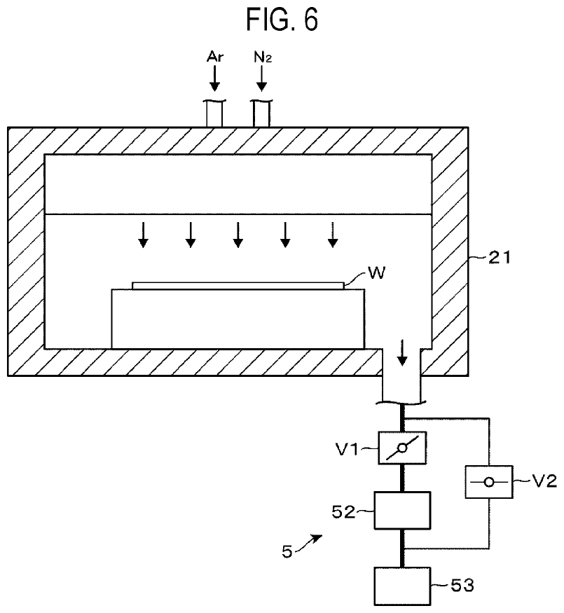

Thereafter, when the degree of opening of the valve V2 is increased (time t4) and the pressure within the processing container 21 is decreased to a predetermined pressure (FIG. 5), the valve V2 is closed, and the valve V1 is opened, so that the operation of the exhauster 5 is switched from the second operation to the first operation. By an action of the TMP 52, exhaust within the processing container 21 rapidly proceeds (FIG. 6, time t5), and the pressure within the processing container 21 becomes 50 Torr or less and, for example, becomes a pressure P2 lower than the pressure P0 (10 Torr) which is the pressure at the start of processing. The pressure P2 corresponds to a second pressure. Subsequently, etching gases remaining within the processing container 21 and various reaction products generated by an action of the etching gases are rapidly exhausted, and the etching is terminated.

A lower part of FIG. 8 shows the wafer W at the end of the etching. As described above, as the etching proceeds, an etching amount of the thermal oxide film 11 is greater than an etching amount of the non-thermal oxide film 12. After the end of the etching, the degree of opening of the valve V1 is adjusted to increase the pressure within the processing container 21 (time t6). When the pressure within the processing container 21 becomes approximately equal to an ambient pressure, the wafer W is unloaded to an outside of the processing container 21 by the transfer mechanism.

As described above, according to the etching apparatus 1, it is possible to etch the thermal oxide film 11 at a relatively high etching rate, and to set the etching rate of the thermal oxide film 11 to be higher than the etching rate of the non-thermal oxide film 12. Hereinafter, for convenience of description, a step of adjusting the temperature of the wafer W and increasing the pressure within the processing container 21 during a period from time t1 to t2 is referred to as a pressure adjustment step, and a step of supplying both the HF gas and the NH₃ gas into the processing container 21 during a period from time t2 to t3 is referred to as a main etching step. In addition, a step of supplying only the inert gases into the processing container 21 without supplying the etching gases in a state in which the pressure within the processing container 21 is relatively high during a period from time t3 to t4 is referred to as a purge step. Further, a step of setting the interior of the processing container 21 to a relatively high degree of vacuum to remove residues within the processing container 21 during a period from time t4 to t6 is referred to as a vacuum step.

In addition, a period from time t1 to t3 during which the HF gas is supplied is a first period, and a process of supplying the HF gas during the period from time t1 to t3 is a first gas supply process. A period from time t2 to t3 during which the NH₃ gas is supplied is a second period and is also a common supply period overlapping the first period. A process of supplying the NH₃ gas during the period from time t2 to t3 is a second gas supply process. In the period from time t2 to t3 during which both the HF gas and the NH₃ gas are supplied, an exhaust process of the processing container 21 performed by the exhauster 5 is a first exhaust process.

Further, an exhaust process performed by the exhauster 5 during a period from time t4 to t6 when the vacuum step is performed is a second exhaust process. In the second exhaust process, an exhaust process performed by the exhauster 5 in the second operation during a period from time t4 to t5 is a pre-exhaust process, and an exhaust process performed by the exhauster 5 in the first operation during a period from time t5 to t6 is a post-exhaust process. Further, the purge step corresponds to a continuous etching process of continuing etching even after the supply of the HF gas and the NH₃ gas is stopped.

When a required etching amount for the thermal oxide film 11 is relatively large, the pressure adjustment step, the main etching step, the purge step, and the vacuum step may be regarded as one cycle, and the cycle may be repeatedly performed. That is, after the vacuum step is terminated at time t6 and before the wafer W is unloaded from the processing container 21, the operations of the apparatus during a period from time t1 to t6 may be performed again. The number of cycle repetitions may be arbitrarily set according to a desired etching amount. In addition, regarding the pressure adjustment step, it has been described that the temperature of the wafer W is adjusted in addition to the adjustment of the pressure within the processing container 21. However, since the temperature adjustment of the wafer W is completed during the pressure adjustment step in a first cycle, only the pressure within the processing container 21 is adjusted in the pressure adjustment steps in second and subsequent cycles.

However, respective supply start timings and supply stop timings of the HF gas and the NH₃ gas supplied into the processing container 21 may be made to coincide with each other. That is, in the process shown in the above chart, the HF gas may not be supplied into the processing container 21 during the period from time t1 to t2, and the supply of the HF gas into the processing container 21 may be started from time t2, so that the supply timings of the HF gas and the NH₃ gas may become same.

However, as shown in the evaluation tests, it is desirable to set a supply start timing of the HF gas earlier than a supply start timing of the NH₃ gas, as in the processing examples described with reference to FIGS. 2 to 7, so that supply time of the HF gas is longer than supply time of the NH₃ gas. By doing so, it is possible to make the etching rate of the thermal oxide film 11 relative to the etching rate of the non-thermal oxide film 12 higher. This is potentially because, when the supply of the NH₃ gas into the processing container 21 is started, the HF gas is already present in the processing container 21, and thus mixing property and reactivity between the gases are increased and an amount of HF₂ generated is increased. In addition, in the chart of FIG. 7, the NH₃ gas may be supplied in place of HF gas during the period in which the HF gas is supplied, and the HF gas may be supplied in place of the NH₃ gas during the period in which the NH₃ gas is supplied. That is, the supply start timing of the NH₃ gas may be made earlier than the supply start timing of the HF gas, so that the supply time of the NH₃ gas is longer than the supply time of the HF gas.

While the processing example in which a supply stop of the HF gas and a supply stop of the NH₃ gas coincide with each other has been described, the supply stop timings of the gases may be different from each other because HF₂ can be generated as long as there is a period during which both the HF gas and the NH₃ gas are simultaneously supplied into the processing container 21 of a relatively high pressure. That is, even after gas supplied into the processing container 21 through one of the gas supply paths 31 and 32 is switched from the etching gas to the inert gas, the etching gas continues to be supplied through the other one of the gas supply paths 31 and 32. Subsequently, gas supplied into the processing container 21 through the other one of the gas supply paths 31 and 32 may be switched from the etching gas to the inert gas.

Further, while the pressure within the processing container 21 during the main etching step and the pressure within the processing container 21 during the purge step are set to the same pressure P1 in the above processing example, the steps may be performed at different pressures. However, since the purge step is also a step to generate HF₂ and to perform processing similarly to the main etching step, it is desirable to perform the purge step at a pressure higher than 50 Torr, as in the main etching step.

The purge step may not be performed, and the vacuum step may be performed after the main etching step. However, as shown in the evaluation tests, it is desirable to perform the purge step because the purge step can increase the etching rate of the thermal oxide film 11 relative to the etching rate of the non-thermal oxide film 12.

After performing the main etching step, for example, by performing exhaust so as to maintain the pressure within the processing container 21 at same pressure as during execution of the main etching step, the etching gases or reaction products remaining within the processing container 21 are removed. That is, the vacuum step in which the interior of the processing container 21 is set to a low pressure may not be performed. However, in order to quickly remove the above-described residues, it is desirable to perform the vacuum step.

In addition, after the wafer W is loaded into the processing container 21, a pretreatment may be performed by supplying a desired gas into the processing container 21 in a state in which the pressure within the processing container 21 is at P0. The type of the pretreatment is arbitrary. For example, it is assumed that a film other than the thermal oxide film 11 and the non-thermal oxide film 12 is formed on a surface of the wafer W. In order to etch the film together with the thermal oxide film 11 and the non-thermal oxide film 12, an oxidation treatment of supplying oxidizing gas such as oxygen (O) or a gas containing O radicals into the processing container 21 may be performed as the pretreatment. Further, when such pretreatment of supplying the gas for the oxidation treatment is performed, a gas supply source and a flow rate adjuster for that gas are provided in the etching apparatus 1 to perform such treatment. The above-described pressure adjustment step may be performed as a step of adjusting the pressure within the processing container 21 after such pretreatment is performed. In addition, in the case in which the pretreatment is not performed, the pressure within the processing container 21 during the period from time t1 to t2, described in FIG. 7 as the period for performing the pressure adjustment step, does not have to be set to P0. Instead, in order to make the pressure within the processing container 21 during the period from time t1 to t2 to become P1, which is the same pressure as during execution of the main etching step, an operation of the exhauster 5 may be controlled.

While the example has been described in which the wafer W having both the thermal oxide film 11 and the non-thermal oxide film 12 formed thereon is processed, the present technology may also be used to processing of the wafer W on which only the thermal oxide film 11 among the films is formed. Further, the present technology may also be applied to processing the wafer W on which only the non-thermal oxide film 12 is formed and the thermal oxide film 11 is not formed, so as to etch the non-thermal oxide film 12. However, from the viewpoint that a high etching rate is obtained, it is particularly desirable to apply the present technology to etching of the thermal oxide film 11.

Since various amines, which are compounds having structures similar to a structure of NH₃, are considered to be capable of generating HF₂⁻, amine gas may be used as basic gas in place of the NH₃ gas. Further, HF₂ may be generated by using chlorine trifluoride (ClF₃) gas or fluorine (F₂) gas as a fluorine-containing gas in place of the HF gas. In addition, while the etching apparatus 1 has been described as having a configuration of a so-called single-wafer processing device in which one wafer W is accommodated and processed in the processing container 21, an apparatus may have a configuration in which a plurality of wafers W is accommodated and processed collectively in the processing container 21.

It is to be noted that the embodiment disclosed herein is exemplary in all respects and is not restrictive. The above-described embodiment may be omitted, replaced, modified, and/or combined in various forms without departing from the scope and spirit of the appended claims.

### [Evaluation Tests]

Evaluation tests conducted in relation to the technology of the present disclosure will be described.

### Evaluation Test 1

As described in Equation 1 and Equation 2, (NH₄) F generated from HF and NH₃ is decomposed to produce HF or HF₂. By performing simulations, a correspondence between a ratio of the number of generated HF₂ molecules to the number of generated HF molecules and a pressure of a space in which the decomposition occurs was investigated. The simulations were conducted while varying the pressure of the space within a range of 10 Torr or more and less than 100 Torr. In addition, a temperature of the space was varied from 70 degrees C. to 130 degrees C. in increments of 10 degrees C., and the above correspondence was investigated at each temperature.

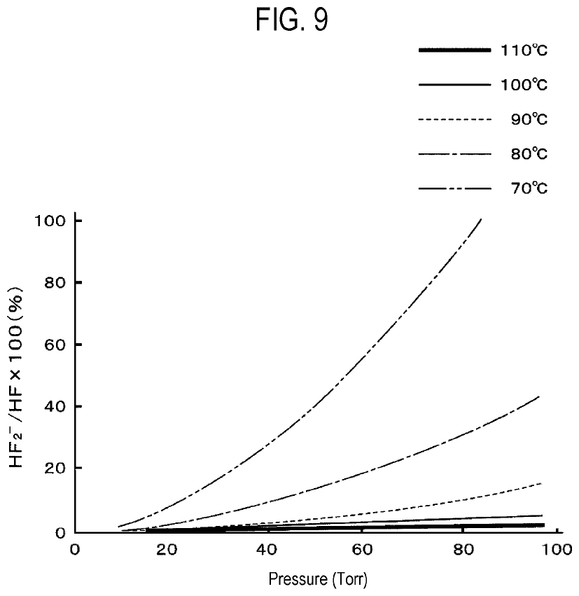

FIG. 9 is a graph showing results of the simulations. The horizontal axis represents the pressure of the space (unit: Torr), and the vertical axis represents “the number of generated HF₂ molecules/number of generated HF molecules×100 (unit: %)”. In addition, since results at 110 degrees C. to 130 degrees C. were substantially same, only a result at 110 degrees C. is shown. As shown in the graph, regardless of a temperature setting, within a pressure range in which measurements were conducted, the higher the pressure, the higher the ratio of the number of HF₂⁻ molecules to the number of HF molecules. Therefore, it was confirmed from Evaluation Test 1 that, in order to generate a large amount of HF₂, it is desirable to set the pressure within the processing container 21 to a relatively high pressure.

### Evaluation Test 2

By using the etching apparatus 1, each wafer W was processed according to a different sequence. Subsequently, etching amounts of the thermal oxide film 11 and the non-thermal oxide film 12 formed on each wafer W were measured, and a difference in the etching amount of the thermal oxide film 11 relative to the etching amount of the non-thermal oxide film 12 (etching amount of thermal oxide film 11-etching amount of non-thermal oxide film 12) was calculated. In addition, the thermal oxide film 11 and the non-thermal oxide film 12 were formed on a surface of the flat underlying film 13 having no concave-convex pattern. Therefore, as shown in FIG. 8, surfaces of the thermal oxide film 11 and the non-thermal oxide film 12 were also flat films. In Evaluation Test 2, the non-thermal oxide film 12 was a TEOS film.

As a processing sequence, any of a first sequence to a fourth sequence was selected and performed. Among them, the fourth sequence corresponds to the processing sequence described in the embodiment with reference to FIGS. 2 to 7. In the fourth sequence, the period from time t1 to t2, which is the pressure adjustment step, was set to 5 seconds, the period from time t2 to t3, which is the main etching step, was set to 5 seconds, the period from t3 to t4, which is the purge step, was set to 60 seconds, and the period from time t4 to t6, which is the vacuum step, was set to 30 seconds. The temperature of the wafer W during the processing was set to 100 degrees C. or higher, as in the embodiment.

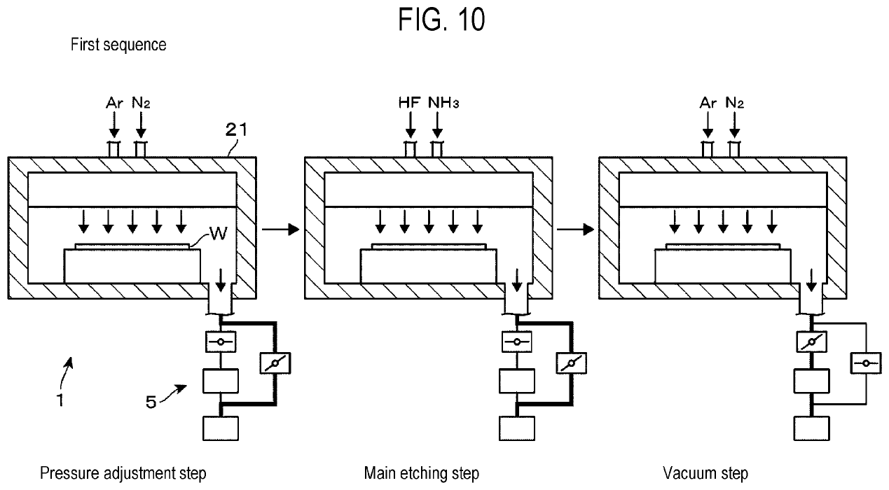

FIGS. 10, 11, and 12 show the first sequence, the second sequence, and the third sequence, respectively. Differences between the first to third sequences and the fourth sequence will be described. As shown in FIG. 10, in the first sequence, the HF gas is not supplied in the pressure adjustment step, and the supply of the HF gas is started at time t2 in the chart of FIG. 7. Therefore, the main etching step is started by starting the supply of both the HF gas and the NH₃ gas. In the first sequence, the purge step is not performed, and the vacuum step is performed after the main etching step. Therefore, when the supply of the HF gas and the NH₃ gas into the processing container 21 is stopped, a pressure reduction in the processing container 21 is started.

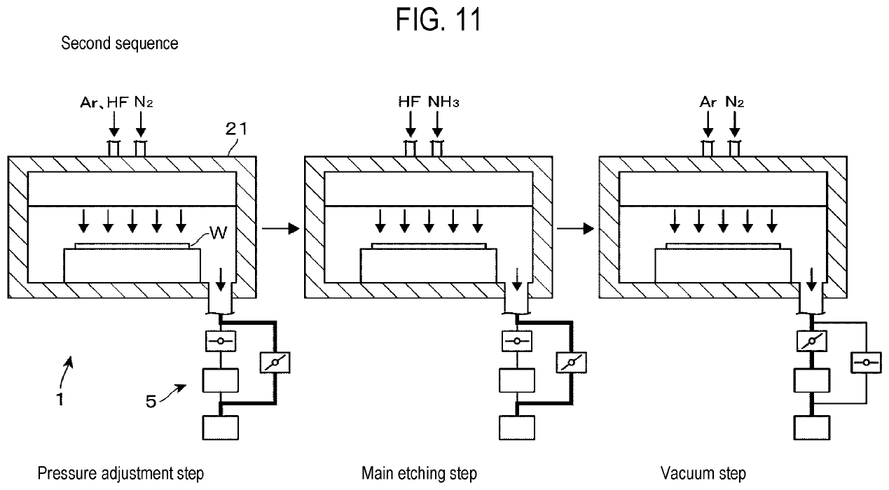

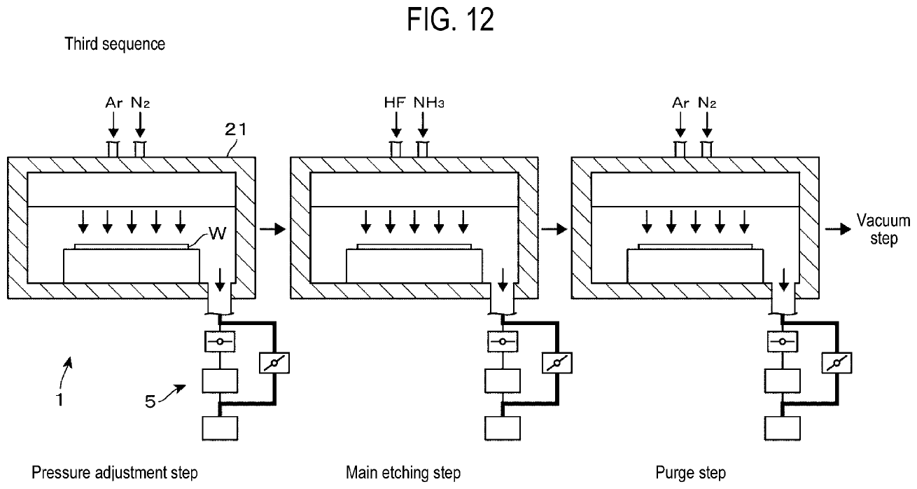

As shown in FIG. 11, in the second sequence, the HF gas is supplied when the pressure adjustment step is started, as in the fourth sequence. However, as in the first sequence, the purge step is not performed. In the third sequence, as shown in FIG. 12, the HF gas is not supplied during the pressure adjustment step as in the first sequence, and the main etching step is started by starting the supply of the HF gas and the NH₃ gas. In the third sequence, the purge step is performed as in the fourth sequence.

Table 1 below shows normalized values obtained by dividing differences between the measured etching amounts after performing the first to fourth sequences and calculated etching amounts by a predetermined positive value. In addition, a larger normalized value corresponds to a larger actual value (a value before normalization).

TABLE 1

| | First | Second | Third | Fourth |
|---|---|---|---|---|
| | Sequence | Sequence | Sequence | Sequence |
| Etching Amount of | 12.5 | 36.5 | 68.5 | 138.0 |
| Thermal Oxide Film | | | | |
| (Normalized Value) | | | | |
| Etching Amount of | 26.1 | 39.2 | 72.5 | 111.0 |
| Non-Thermal Oxide Film | | | | |
| (Normalized Value) | | | | |
| Etching Difference | −13.6 | −2.7 | −4.0 | +27.0 |

From the results of the first to fourth sequences described above, it can be understood that the etching rate of the thermal oxide film 11 can be increased by supplying the HF gas into the processing container 21 prior to the NH₃ gas or by performing the purge step. In the fourth sequence in which both the prior supply of the HF gas and the purge step are performed, it was confirmed, as described in the embodiment, that the etching rate of the thermal oxide film 11 can be made higher than the etching rate of the non-thermal oxide film 12, which is the TEOS film.

However, as described above, in Evaluation Test 2, the non-thermal oxide film 12, which is a silicon oxide film, is the TEOS film. In a film formation process of the TEOS film, an element other than silicon and oxygen, such as carbon or hydrogen which constitutes a film formation gas, is incorporated into the film. That is, since the TEOS film can be regarded as a silicon oxide film containing impurities, and an atomic arrangement of each silicon (Si) and oxygen (O) is not dense, a robustness of the TEOS film is lower than a robustness of the thermal oxide film 11. Similarly, since a film other than the TEOS film such as BSG exemplified as the non-thermal oxide film 12 can be regarded as having a structure in which an element other than Si and O is incorporated into the silicon oxide, the film is less robust than the thermal oxide film 11. Further, since a silicon oxide film formed by oxidizing a Si film under a plasma environment is damaged by plasma during formation or has a less dense arrangement of Si and O compared to the thermal oxide film 11, a robustness of the silicon oxide film is low. Considering structures and properties of the respective films, even if the non-thermal oxide film 12 were one of the above-described films other than the TEOS film, it is expected that results similar to the results of Evaluation Test 2 using the TEOS film would be obtained.

In addition, a pressure within the processing container 21 during the main etching step and the purge step in Evaluation Test 2 was 90 Torr, which is the same as in the embodiment. As shown in Evaluation Test 1 described above, up to around 100 Torr, the higher the pressure, the more HF₂ is generated, and under a relatively high temperature, the amount of the generated HF does not fluctuate largely even when the pressure changes. In view of the results of Evaluation Tests 1 and 2, it is considered desirable to set the pressure within the processing container 21 during the main etching step and the purge step, for example, to 70 Torr (9.33×10³ Pa) to 100 Torr (1.33×10⁴ Pa).

Further, when comparing the results of the first and second sequences with the results of the third and fourth sequences in Evaluation Test 2, it can be seen that performing the purge step is effective in increasing the etching rate of the thermal oxide film 11. However, even in the first and second sequences in which the purge step is not performed, the pressure within the processing container 21 is relatively high immediately after the start of the vacuum step, and the inert gas is still being supplied into the processing container 21. In other words, a state similar to a state during the execution of the purge step is formed. That is, when a duration of performing a process of supplying the inert gas at a relatively high pressure is short, a sufficient continuous etching effect cannot be obtained.

Therefore, it is desirable to set the purge step to have a sufficient duration. For example, as in the third and fourth sequences of Evaluation Test 2, it is desirable to set the purge step to execute for a period longer than the period (time t1 to t3) during which any of the etching gases are supplied into the processing container 21. In addition, as described above, a supply stop timing of the etching gases is not limited to being matched between the HF gas and the NH₃ gas as in the example shown in the chart of FIG. 7. However, a start timing of the purge step is a timing at which the supply of all of the etching gases into the processing container 21 is stopped and the supply of the inert gases from each of the gas supply paths 31 and 32 is performed. Further, an end timing of the purge step is, as shown as time t4 in FIG. 7, a timing at which the pressure within the processing container 21 starts to decrease toward a pressure of 50 Torr or less, that is, a timing within a period during which the pressure within the processing container 21 continues to be lowered until the pressure reaches 50 Torr or less.

Additionally, performing the etching of the thermal oxide film 11 can be considered by performing the main etching step for a relatively long time without performing the purge step. However, in that case, it was confirmed that the etching rate of the thermal oxide film 11 could not be made sufficiently higher than the etching rate of the non-thermal oxide film 12, and thus an effectiveness of performing the purge step is demonstrated. The reason that the etching rate of the thermal oxide film 11 did not increase sufficiently is presumed to be that a progress of a reaction of Equation 1 was enhanced relative to Equation 2, so that etching, in which AFS described in the background art is generated, proceeded relatively well, whereas etching due to an action of HF₂ was less likely to proceed. In addition, in Evaluation Test 2, while etching was performed on the thermal oxide film 11 and the non-thermal oxide film 12 formed on the underlying film 13 having no concave-convex pattern, it is considered that a reactivity of each film does not change depending on the presence or absence of the concave-convex pattern. That is, etching may be performed on the thermal oxide film 11 and the non-thermal oxide film 12 formed on the concave-convex pattern. In that case as well, it is considered that etching selectivity having same tendency as the etching selectivity shown in Evaluation Test 2 is obtained with respect to the thermal oxide film 11 and the non-thermal oxide film 12.

According to the present disclosure, it is possible to etch a silicon oxide film at a desirable etching rate.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An etching method, comprising:
a first gas supply process of supplying a fluorine-containing gas during a first period into a processing container which accommodates a substrate on which a silicon oxide film is formed;
a second gas supply process of supplying a basic gas into the processing container during a second period including a common supply period overlapping the first period; and
a first exhaust process of exhausting an interior of the processing container so that a pressure within the processing container during the common supply period becomes a first pressure greater than 50 Torr to perform etching of the silicon oxide film by the fluorine-containing gas and the basic gas.

2. The etching method of claim 1, wherein the fluorine-containing gas is hydrogen fluoride gas, and
wherein the basic gas is ammonia gas.

3. The etching method of claim 2, further comprising:
after the first exhaust process, a second exhaust process of exhausting the interior of the processing container so that the pressure within the processing container becomes a second pressure of 50 Torr or less, which is lower than the first pressure.

4. The etching method of claim 3, wherein an upstream end of a first exhaust path is connected to the processing container, a downstream end of the first exhaust path is connected to a first exhaust mechanism, and a first valve and a second exhaust mechanism are interposed and installed in the first exhaust path in this order toward a downstream side of the first exhaust path,
wherein an upstream end and a downstream end of a second exhaust path in which a second valve is provided are connected to an upstream side of the first valve in the first exhaust path and to a downstream side of the second exhaust mechanism in the first exhaust path, respectively, and
wherein the second exhaust process includes:
a pre-exhaust process in which the first valve is closed and the interior of the processing container is exhausted by the first exhaust mechanism; and
subsequently, a post-exhaust process in which the second valve is closed and the interior of the processing container is exhausted by the first exhaust mechanism and the second exhaust mechanism.

5. The etching method of claim 3, further comprising:
after the first exhaust process and before continuously lowering the pressure within the processing container until the pressure reaches the second pressure, a continuous etching process of supplying an inert gas into the processing container to continue performing etching in a state in which a supply of the fluorine-containing gas and the basic gas into the processing container is stopped.

6. The etching method of claim 5, wherein a period during which the continuous etching process is performed is longer than a period during which any one of the fluorine-containing gas and the basic gas is supplied into the processing container.

7. The etching method of claim 6, wherein the silicon oxide film includes a thermal oxide film.

8. The etching method of claim 7, wherein the silicon oxide film includes the thermal oxide film and another silicon oxide film of a different type from the thermal oxide film.

9. The etching method of claim 3, wherein one of the first period and the second period precedes the other of the first period and the second period, and is longer than the other period.

10. The etching method of claim 9, wherein the one of the first period and the second period is the first period.

11. The etching method of claim 10, wherein the silicon oxide film includes a thermal oxide film.

12. The etching method of claim 11, wherein the silicon oxide film includes the thermal oxide film and another silicon oxide film of a different type from the thermal oxide film.

13. The etching method of claim 1, wherein the first pressure is in a range of 70 Torr to 100 Torr.

14. The etching method of claim 1, further comprising:
a process of setting a temperature of the substrate during the common supply period to 100 degrees C. or higher.

15. The etching method of claim 1, wherein the silicon oxide film includes a thermal oxide film.

16. An etching apparatus comprising:
a processing container configured to accommodate a substrate on which a silicon oxide film is formed;
a first gas supply configured to supply a fluorine-containing gas into the processing container during a first period;
a second gas supply configured to supply a basic gas into the processing container during a second period including a common supply period overlapping with the first period; and
an exhauster configured to exhaust an interior of the processing container so that a pressure within the processing container during the common supply period becomes a first pressure greater than 50 Torr to perform etching of the silicon oxide film by the fluorine-containing gas and the basic gas.
